(19) United States
(12) Patent Application Publication
(10) Pub. No.: US 2023/0253278 A1
(43) Pub. Date: Aug. 10, 2023

(54) SEMICONDUCTOR MODULE WITH INTEGRATED CURRENT SENSOR

(71) Applicant: AUDI AG, Ingolstadt (DE)

(72) Inventors: Christoph MEIER, Eitensheim (DE); Benjamin SÖHNLE, Ingolstadt (DE)

(21) Appl. No.: 18/166,361

(22) Filed: Feb. 8, 2023

(30) Foreign Application Priority Data
Feb. 9, 2022 (DE) 102022102966.2

(51) Int. Cl. H01L 23/31; H02M 7/00; H01L 23/498; H02M 7/537; B60L 53/20

(52) U.S. Cl. CPC H01L 23/3121; H02M 7/003; H01L 23/49811; H02M 7/537; B60L 53/20; B60L 2210/40

(57) ABSTRACT

Systems include a semiconductor power module embedded in plastic and having an integrated current metering unit, for example, for a pulse inverter of an electric vehicle, an arrangement including the module, and a method for its manufacture.

### BACKGROUND

### Technical Field

The subjects of some embodiments of the invention are a semiconductor power module, an arrangement including the module, and a method for its manufacture.

### Description of the Related Art

A pulse inverter consists of a capacitor, a drive circuit board, a power module and a current metering unit. The current metering unit is connected either as an external component or together with the power module as a unit integrated in the power box. The incorporation of current sensors for the metering of the currents results in a large space requirement and additional costs and additional weight.

CN 1 13 295 913 A discloses a power module structure with an integrated current sensor. The structure comprises a radiator, a plastic sleeve, a copper-lined ceramic substrate, a wafer, a cover plate and an alternating current busbar. The copper-lined ceramic substrate is arranged on the surface of the radiator, the wafer is arranged on the copper-lined ceramic substrate to form a control circuit, and the plastic sleeve is arranged on the radiator and encloses the copper-lined ceramic substrate. The alternating current busbar is connected to the copper-lined ceramic substrate and protrudes from the plastic sleeve; and the cover plate is arranged on the top side of the plastic sleeve. The structure moreover comprises a current metering chip, a current metering board, and a metal shielding cover. The current metering chip is soldered on the current metering board, and the current metering board is arranged on the plastic shell and lies directly opposite the alternating current busbar protruding from the plastic sleeve. The metal shielding cover encloses the alternating current busbar and the current metering board, and the current metering chip recognizes a current signal of the alternating current busbar.

EP 3 748 369 A1 reveals an integrated current metering device for measuring a current by integrated use of a Hall sensor and a shunt resistor. The integrated current metering device comprises a printed circuit board, a shunt resistor with a resistor element having a predetermined resistance value and terminals which extend out from both sides of the resistor element. The shunt resistor is mounted on the bottom side of the circuit board and a Hall sensor is mounted on the top side of the printed circuit board and faces toward the shunt resistor, the circuit board being arranged between the Hall sensor and the shunt resistor.

DE 10 2018 109 803 A1 relates to a power electronic unit for an electrical drive, having an electrically conductive substrate element and a power semiconductor module arranged on the substrate element, converting a direct current into a three-phase alternating current. A current sensor used to determine the alternating current is integrated such that it forms a main module together with the substrate element and the power semiconductor module.

### BRIEF SUMMARY

Some embodiments include a semiconductor power module embedded in plastic and having an integrated current metering unit, for example, for a pulse inverter of an electric vehicle, an arrangement including the module, and a method for its manufacture.

Some embodiments provide a semiconductor power module having a smaller space requirement and less weight than conventional semiconductor power modules having an external current metering unit or one integrated in the power box.

In some embodiments, a current metering unit consisting of a current sensor IC, a current sensor board (PCB), and a U-shield is integrated in the plastic encased (molded) semiconductor power module. The module can simply be mounted by means of a press-fit connection on a circuit board (PCB) and it has an embedded protective plate (U-shield) to increase the noise immunity.

Some embodiments include a semiconductor power module for a pulse inverter of an electric vehicle which is encased in a plastic compound. The plastic encasing can be produced for example by casting the electronic components of the module with a casting resin in an appropriate mold.

A busbar, an integrated circuit arranged on a circuit board for current metering (current sensor IC), and a U-shaped shield plate surrounding the busbar and the circuit board with the current sensor IC are likewise embedded in the plastic compound of the semiconductor power module and surrounded by it, while one end of the busbar and electrical terminal contacts of the circuit board protrude from the plastic compound. In one embodiment, the end of the busbar protrudes from a front face or side surface of the semiconductor power module. In another embodiment, the end of the busbar protrudes from the top side or the bottom side of the semiconductor power module. In one embodiment, the electrical terminal contacts protrude from the top side of the semiconductor power module. In another embodiment, the electrical terminal contacts protrude from the bottom side of the semiconductor power module. In yet another embodiment, the electrical terminal contacts protrude from a front face or side surface of the semiconductor power module.

In one embodiment, the semiconductor power module comprises terminal lugs for the electrical contacting of the semiconductor power module, which protrude from the plastic compound. In one embodiment, the terminal lugs protrude from a front face or a side surface of the semiconductor power module. In another embodiment, the terminal lugs are bent upward and their ends point in the direction of the top side of the semiconductor power module. In another embodiment, the terminal lugs protrude from the top side of the semiconductor power module. In yet another embodiment, the terminal lugs protrude from the bottom side of the semiconductor power module.

Some embodiments include an arrangement of a semiconductor power module as described herein and a drive circuit board for the semiconductor power module. In the arrangement, the integrated circuit for current metering is connected by the electrical terminal contacts to the drive circuit board in electrically conductive manner.

In one embodiment of the arrangement, the semiconductor power module is also connected in electrically conductive manner by the terminal lugs for the electrical contacting of the semiconductor power module to the drive circuit board.

Some embodiments include a method for manufacturing the arrangement as described herein. For this, the semiconductor power module is mounted on the drive circuit board and the electrical terminal contacts and optionally the terminal lugs for the electrical contacting of the semiconductor power module are secured in corresponding openings of the drive circuit board by press-fit.

The benefits of the solution according to the invention include a reduction of the design space needed for the inverter and a more cost-favorable dimensioning of the current metering unit. The semiconductor and the current metering unit are integrated in a single component, no additional connector is required, and no additional shielding elements are needed. Further benefits and embodiments will emerge from the description and the accompanying drawings.

Of course, the features explained above and those yet to be explained below can be used not only in the particular indicated combination, but also in other combinations or standing alone.

### BRIEF DESCRIPTION OF THE SEVERAL VIEWS OF THE DRAWINGS

Embodiments are shown schematically with the aid of the drawing and shall be further described with reference to the drawing.

FIG. 1 is a perspective representation of a portion of one embodiment of the power module.

FIG. 2 is a sectional representation of the power module shown in FIG. 1 and a drive circuit board.

### DETAILED DESCRIPTION

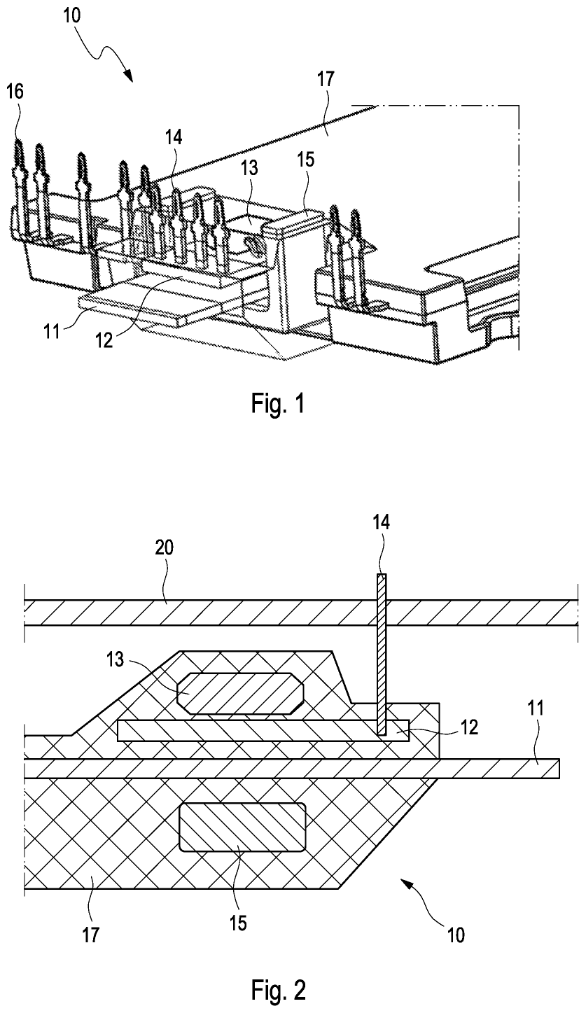

FIG. 1 shows schematically a perspective representation of a cutout feature of one embodiment of the power module 10. Embedded in a plastic body 17 (encasing mold) of the power module 10 are a busbar 11, a circuit board 12 (PCB), carrying an integrated circuit for the current metering 13 (metering IC), and electrical contacts 14 for connection to a drive circuit board 20. Arranged around the busbar 11 and the circuit board 12 is a U-shaped shield plate 15 (U shield), which is likewise embedded in the plastic body 17, the ends of the U-shaped shield plate 15 protruding from the top surface of the plastic body 17. One end of the busbar 11 protrudes at one front face of the plastic body 17 out from it, as do electrical terminal lugs 16 of the power module 10. The ends of the electrical contacts 14 likewise protrude out from the top surface of the plastic body 17.

FIG. 2 shows schematically a portion of a longitudinal section of the power module 10 shown in FIG. 1 and a drive circuit board 20 for the power module 10. The integrated circuit for current metering 13 which is embedded in the plastic body 17 of the power module 10 is connected in electrically conducting manner across the circuit board 12 and the electrical terminal contacts 14 to the drive circuit board 20. The U-shaped shield plate 15 shields the integrated circuit for current metering 13, the circuit board 12 and the busbar 11 against interference fields and thus heightens the noise immunity of the power module 10. The power module 10 can be simply mounted on the drive circuit board 20 (press-fit), no additional connectors are needed.

German patent application no. 10 2022 102966.2, filed Feb. 9, 2022, to which this application claims priority, is hereby incorporated herein by reference in its entirety.

Aspects of the various embodiments described above can be combined to provide further embodiments. In general, in the following claims, the terms used should not be construed to limit the claims to the specific embodiments disclosed in the specification and the claims, but should be construed to include all possible embodiments along with the full scope of equivalents to which such claims are entitled.

1. A system, comprising:
a semiconductor power module encased in a plastic compound for a pulse inverter of an electric vehicle,
wherein a busbar, an integrated circuit for current metering arranged on a circuit board, and a U-shaped shield plate surrounding the busbar and the circuit board are embedded in the plastic compound of the semiconductor power module and surrounded by it, while one end of the busbar and electrical terminal contacts of the circuit board protrude from the plastic compound.

2. The system according to claim 1, wherein terminal lugs for the electrical contacting of the semiconductor power module protrude from the plastic compound.

3. The system according to claim 1, wherein the end of the busbar protrudes from a front face of the semiconductor power module.

4. The system according to claim 1, wherein the electrical terminal contacts protrude from the top side of the semiconductor power module.

5. The system according to claim 2, wherein the terminal lugs for the electrical contacting of the semiconductor power module protrude from a front face of the semiconductor power module.

6. The system according to claim 5, wherein the terminal lugs are bent upward and their ends point in the direction of the top side of the semiconductor power module.

7. The system according to claim 1, further comprising:
a drive circuit board for the semiconductor power module, wherein the integrated circuit for current metering is connected in electrically conductive manner by the electrical terminal contacts to the drive circuit board.

8. The system according to claim 7, wherein the semiconductor power module is connected in electrically conductive manner by the terminal lugs for the electrical contacting of the semiconductor power module to the drive circuit board.

9. A method for manufacturing a system comprising a semiconductor power module encased in a plastic compound for a pulse inverter of an electric vehicle, wherein a busbar, an integrated circuit for current metering arranged on a circuit board, and a U-shaped shield plate surrounding the busbar and the circuit board are embedded in the plastic compound of the semiconductor power module and surrounded by it, while one end of the busbar and electrical terminal contacts of the circuit board protrude from the plastic compound, and a drive circuit board for the semiconductor power module, wherein the integrated circuit for current metering is connected in electrically conductive manner by the electrical terminal contacts to the drive circuit board, the method comprising:
mounting the semiconductor power module on the drive circuit board; and
securing the electrical terminal contacts in corresponding openings of the drive circuit board by press-fit.

10. The method according to claim 9, in which the terminal lugs for the electrical contacting of the semiconductor power module are secured in corresponding openings of the drive circuit board by press-fit.
